(19) United States
(12) Patent Application Publication
(10) Pub. No.: US 2015/0054504 A1
(43) Pub. Date: Feb. 26, 2015

(54) OPTICALLY PUMPED MAGNETOMETER AND METHOD OF MEASURING MAGNETIC FORCE

(71) Applicant: CANON KABUSHIKI KAISHA, Tokyo (JP)

(72) Inventors: Sunao Ichihara, Kawasaki-shi (JP); Tetsuo Kobayashi, Kyoto-shi (JP); Kiyoshi Ishikawa, Kusatsu-shi (JP)

(73) Assignee: Canon Kabushiki Kaisha, Tokyo (JP)

(21) Appl. No.: 14/388,505

(22) PCT Filed: Mar. 26, 2013
(86) PCT No.: PCT/JP2013/059802

§ 371 Date: Sep. 26, 2014

(30) Foreign Application Priority Data
Mar. 29, 2012 (JP) 2012-075619

(51) Int. Cl. G01R 33/26

(52) U.S. Cl. CPC G01R 33/26
USPC 324/305

(57) ABSTRACT

An optically pumped magnetometer includes: a modulation unit which allows rectangular wave modulation to an angle of a polarization plane of probe light; a detector for detecting a change of the angle of the polarization plane of the probe light transmitted through a cell; and a differential circuit for obtaining a difference in light intensity between components separated by a polarization splitter. Thus, both a reduction of a light intensity noise of the probe light and a separation and reduction of a noise defined by an inverse of a frequency in a low frequency area can be achieved.

### TECHNICAL FIELD

The present invention relates to an optically pumped magnetometer and a method of measuring magnetic force, and more particularly, to an optically pumped magnetometer and a method of measuring magnetic force using an electron spin or a nuclear spin of an atom.

### BACKGROUND ART

An optically pumped magnetometer has been known as a magnetometer that includes a cell in which an alkali metal gas is contained, a pump light source for emitting pump light, and a probe light source for emitting probe light, and is configured to detect a fine magnetic field. The details are found in, for example, Non Patent Literature 1.

Because a spin of an atom cluster polarized (optically pumped) by the pumping light rotates upon receiving a magnetic field to be measured, the optically pumped magnetometer is configured to measure the rotation of the spin as a rotation of a plane of polarization (hereinafter referred to as “polarization plane”) of the probe light.

Non Patent Literature 1 discloses a method of modulating the polarization plane of the probe light with a sinusoidal wave by using a phase modulation element in order to reduce a noise of a low frequency area. Non Patent Literature 1 further discloses, apart from the above-mentioned method, a method of reducing a light intensity noise by detecting a rotation of the polarization plane due to the magnetic field by using a polarization splitter in a balanced manner.

### CITATION LIST

### Non Patent Literature

NPL 1: S. J. Seltzer. “Developments in Alkali-Metal Atomic Magnetometry,” Dissertation, Princeton University (2008)

### SUMMARY OF INVENTION

### Technical Problem

However, the method disclosed in the above-mentioned Non Patent Literature 1 has the following problems. In Non Patent Literature 1, in order to reduce an influence of a noise that has power defined by an inverse of a frequency, modulation driving is performed with the sinusoidal wave, and a measured signal is shifted to a high frequency area, thus separating and reducing the noise.

However, this measurement method has a problem that a light intensity noise of the probe light cannot be reduced.

In Non Patent Literature 1, as another method, an example of difference detection using a polarization splitter is disclosed, which is a polarization measurement method of reducing the light intensity noise of the probe light.

However, this method of simply combining two methods described above, in which the light intensity noise is reduced by the balanced detection while the noise in the low frequency area is separated and reduced by the sinusoidal wave modulation, has the following problem.

That is, because a position of the polarization plane is shifted from an angle of the balanced detection due to an oscillation caused by the modulation, the light intensity noise cannot be fully reduced.

Details on analysis of these problems are described later as comparative examples in the description of embodiments of the present invention.

### Solution to Problem

The present invention is directed to an optically pumped magnetometer and a method of measuring magnetic force, which can achieve both a reduction of a light intensity noise of probe light and a separation and reduction of a noise that is defined by an inverse of the frequency in the low frequency area.

According to one aspect of the present invention, there is provided an optically pumped magnetometer using one of an electron spin and a nuclear spin of an atom, which includes:

a cell containing a group of alkali metal atoms therein;
a probe light optical system for making probe light having a linearly polarized light component enter the cell;
a modulation unit for applying modulation to an angle of a polarization plane of the probe light; and
a detector for detecting a change of the angle of the polarization plane of the probe light transmitted through the cell,
in which the modulation unit allows rectangular wave modulation to the angle of the polarization plane of the probe light, and
in which the detector includes:
a polarization splitter; and
a differential circuit for obtaining a difference in light intensity between components separated by the polarization splitter.

Further, according to another aspect of the present invention, there is provided a magnetic force measurement method of measuring a magnetic field intensity, which includes the steps of:

preparing a cell containing a group of alkali metal atoms therein;
making probe light having a linearly polarized light component enter the cell;
applying modulation to an angle of a polarization plane of the probe light; and
detecting a change in the angle of the polarization plane of the probe light transmitted through the cell, in which the modulation applying step includes applying rectangular wave modulation to the angle of the polarization plane of the probe light, and
in which the detecting step comprises measuring a difference in light intensity between components separated by use of a polarization splitter.

### Advantageous Effects of Invention

According to the present invention, the light intensity noise of the probe light can be reduced, and the noise that is defined by the inverse of the frequency in the low frequency area can be separated and reduced.

Further features of the present invention will become apparent from the following description of exemplary embodiments with reference to the attached drawings.

### BRIEF DESCRIPTION OF DRAWINGS

FIG. 1 is a schematic diagram illustrating a configuration example of an optically pumped magnetometer according to an embodiment of the present invention.

FIG. 2 is a schematic cross-sectional view illustrating a configuration example of an optically pumped magnetometer according to an embodiment of the present invention.

FIG. 3 is a schematic diagram illustrating a polarization state of a linearly polarized probe light in an optically pumped magnetometer according to an embodiment of the present invention.

FIG. 4 is a graph showing, with a black line portion, a difference between an output from a photodetector arranged at a transmission port and an output from a photodetector arranged at a reflection port of a polarization splitter according to an embodiment of the present invention.

FIG. 5 is a schematic diagram illustrating a polarization state of linearly polarized probe light according to a comparative example, as opposed to FIG. 3.

FIG. 6 is graph showing, with a black line portion, a difference between an output from a photodetector arranged at a transmission port and an output from a photodetector arranged at a reflection port of a polarization splitter according to a comparative example, as opposed to FIG. 4.

FIG. 7 illustrates a case where a polarization beam splitter is used as a polarization splitter in an optically pumped magnetometer according to an embodiment of the present invention.

### DESCRIPTION OF EMBODIMENTS

A configuration example of an optically pumped magnetometer using an electron spin or a nuclear spin of an atom according to an embodiment of the present invention is described below.

An optically pumped magnetometer according to the embodiment of the present invention includes: a cell containing a group of alkali metal atoms therein; a probe light optical system for making probe light having a linearly polarized light component enter the cell; a modulation unit for applying modulation to an angle of a polarization plane of the probe light; and a detector for detecting a change of the angle of the polarization plane of the probe light transmitted through the cell.

Further, the optically pumped magnetometer is configured so that a rectangular wave modulation is applied to the polarization plane of the probe light by the modulation unit, and then a rotation angle of the polarization plane is detected by the detector by using a polarization splitter and a differential circuit.

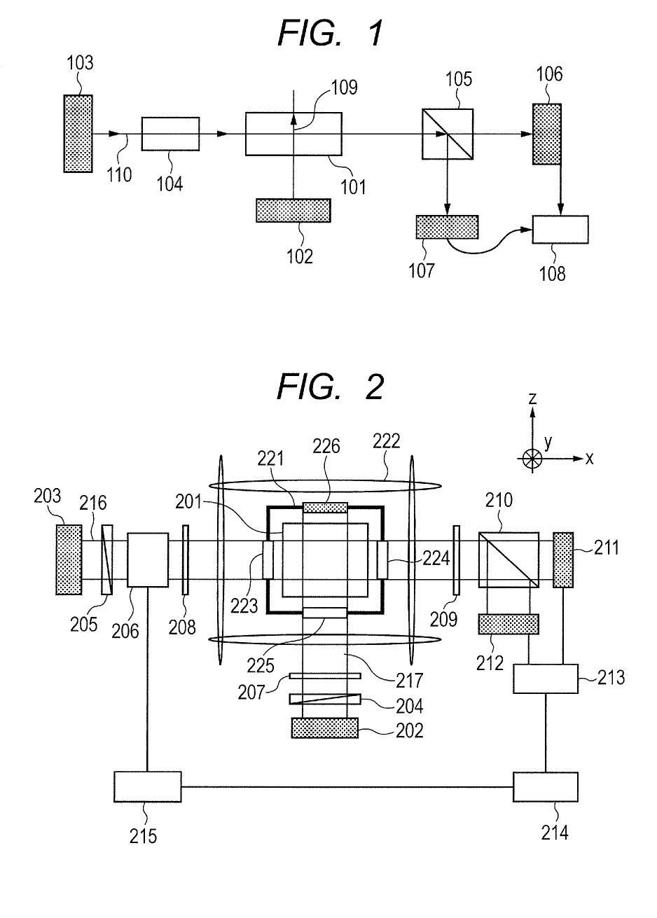

Specifically, as illustrated in FIG. 1, the optically pumped magnetometer includes a cell 101 containing a group of alkali metal atoms (atom cluster) of potassium (K), rubidium (Rb), cesium (Cs), and the like.

In the following description, a case where potassium atom is used as an alkali metal atom is described.

The optically pumped magnetometer further includes a pump light source 102, a probe light source 103, a polarization plane modulation system (modulation unit) 104, a polarization splitter 105, photodetectors 106 and 107, and a differential circuit 108.

Pump light 109 emitted from the pump light source 102 is circularly polarized.

The pump light 109 aligns a spin direction of the potassium atom in the cell 101 by optical pumping, thus polarizing the spin direction.

At this time, a wavelength of the pump light 109 is set to a D1 transition wavelength of the potassium atom.

The spin of the spin-polarized atom performs precession movement by receiving a torque in accordance with a measured magnetic field.

Probe light 110 emitted from the probe light source 103 and entering the cell 101 is linearly polarized.

The probe light 110 emitted from the probe light source 103 transmits through the polarization plane modulation system 104, and the polarization plane of the probe light 110 is modulated.

As another means for modulating the polarization plane of the probe light 110, there is a method of making multiple linearly polarized light beams having different polarizations from each other enter the cell 101 as the probe light 110 in an alternately switching manner. In terms of stabilization of the polarization plane, this configuration is advantageous because the polarization plane modulation system 104 is not required.

On the contrary, when the polarization plane modulation system 104 is used, this configuration is advantageous in terms of simplicity because only one light source is required.

In the following description, a case of using the polarization plane modulation system 104 is described.

The polarization plane of the probe light 110 transmitted through the cell 101 is subjected to paramagnetic Faraday rotation in accordance with the precession movement of the spin. The probe light 110 then enters the polarization splitter 105 and is divided into reflected light and transmitted light depending on the intensity in accordance with the polarization plane.

The light transmitted through the polarization splitter 105 is detected by the photodetector 106 and the light reflected at the polarization splitter 105 is detected by the photodetector 107, and a difference between the transmitted light and the reflected light is measured by the differential circuit 108.

When the polarization splitter 105 is an ideal polarization splitter, all the incident light transmits through the polarization splitter at a certain rotation angle of the polarization plane. This rotation angle is set to θ₀=0°.

At this time, polarized light having an angle of 90° with respect to the angle θ₀ is all output from the reflection side of the polarization splitter 105. At this time, when the light is incident at an angle of the polarization plane of 45° or −45°, the light is divided into the transmitted light and the reflected light with the equal intensity.

At this time, because outputs of the photodetectors 106 and 107 are equal to each other, an output of the differential circuit 108 becomes zero.

Therefore, an initial polarization plane is adjusted to have an angle of θ₀=45° or θ₀=−45° when there is no measured magnetic field. With this configuration, the noise such as the light intensity noise influences the output of the photodetector 106 on the transmission side and the output of the photodetector 107 on the reflection side in the same manner, and the noises are canceled out in the output of the differential circuit 108, thus reducing the noise.

Consider a case where the polarization plane is modulated with a frequency ω_{mod} by the polarization plane modulation system 104 and an oscillation magnetic field oscillating at an angular frequency of ωₛ is measured as the measured magnetic field.

At this time, the output V(t) of the differential circuit 108 is represented by (Expression 1) below.

$$V ( t ) = {V}_{0} cos ( 2 β sin ( \text{?} t + \text{?} ) + 2 {θ}_{0} + 2 f ( \text{?} , \text{?} , \text{?} , t ) )$$

$$\text{?} \text{indicates text missing or illegible when filed}$$

In (Expression 1), V₀ is a conversion coefficient in converting the polarization angle into an output of a differential amplifier, β is the amplitude of the rotation of the polarization plane due to the spin of the atom rotated by the measured magnetic field, θ₀ is an initial polarization angle before the incidence on the polarization plane modulation system 104, and φₛ is the phase of a signal.

The following expression represents a function of the modulation applied on the polarization plane of the probe light 110.

f(α_{mod},ω_{mod},φ_{mod},t)

In this expression, α_{mod} is the amplitude of the modulation, ω_{mod} is a modulation frequency, and φ_{mod} is the phase of the modulation.

Consider a case of entrance of a rectangular wave whose polarization plane takes an angle of 45° and an angle of −45° in an alternate manner as a modulation signal.

That is, in any polarization state, when the rotation of the polarization plane due to the magnetic field is zero, this angle of the polarization plane causes the light to be divided into the transmitted light and the reflected light with the equal intensity by the polarization splitter 105.

In this case, the function of the modulation can be represented by the following expression.

$$f ( {α}_{mod} , {ω}_{mod} , {φ}_{mod} , t ) = \frac{π}{4} sgn ( sin ( {ω}_{mod} t + {φ}_{mod} ) )$$

In this expression, the following expression represents a signum function that oscillates at the angular frequency ω_{mod}.

sgn(sin(ω_{mod}t+φ_{mod}))

When measuring a fine magnetic field, β<<1, and (Expression 1) is modified as (Expression 2).

$$V ( t ) = {V}_{0} cos ( 2 β sin ( {ω}_{s} t + {φ}_{s} ) + 2 {θ}_{0} + 2 \cdot \frac{π}{4} sgn ( sin ( {ω}_{mod} t + {φ}_{mod} ) ) ) \\ \approx {V}_{sin , 0} + {V}_{cos , 1}$$

In (Expression 2), V_{sin,0} and V_{cos,1} are represented by (Expression 3) below.

$${V}_{sin , 0} = \frac{4 {V}_{0}}{π} {J}_{0} ( 2 β ) sin ( 2 {θ}_{2} ) \text{?} \frac{sin ( ( 2 k - 1 ) ( {ω}_{mod} t + {φ}_{mod} ) )}{2 k - 1}$$

$$\text{?} \text{indicates text missing or illegible when filed}$$

In (Expression 3), J₀ and J₁ are the zeroth-order and first-order Bessel functions, respectively.

V_{sin,0} is an oscillation of the polarization plane by the modulation, and V_{cos,1} is a response to the measured magnetic field.

When θ₀ is 0° or 90°, V_{sin,0} becomes zero, and V_{cos,1} is maximized.

This indicates that the light is divided by the polarization splitter 105, and components other than the signal component are differentiated and canceled out by the difference between the outputs of the photodetectors 106 and 107.

When the polarization splitter 105 is not an ideal crystal, or when a direct-current (DC) component is not canceled out but remains at the angle θ₀ of 45° or −45° due to a distortion of optical arrangement or the like, the initial phase and the amplitude of the rectangular wave may be finely adjusted to take a balance therebetween.

Consider a case where the probe light 110 has a light intensity noise and fluctuates at the time of measurement.

At this time, time dependency may be applied by setting V₀ to V₀(t) in (Expression 2). When a power spectral component of a noise that is defined by an inverse of the frequency is represented as follows.

\tilde{V}_{sys}(ω)

From some calculation, βₘᵢₙ as the lower limit of β is represented by the following expression.

$${β}_{min} \approx \frac{π}{2} \frac{\vert {\tilde{V}}_{sys} ( {ω}_{mod} + {ω}_{s} ) \vert}{{\tilde{V}}_{0} ( 0 )}$$

The following expression in the above-mentioned expression represents an average intensity of the probe light 110.

\tilde{V}₀(0)

In this embodiment, the light intensity noise is reduced because the operation is performed in a balanced position where the DC components are constantly canceled out.

A case where the modulation function is a sinusoidal wave is considered as a comparative example. In the case of the sinusoidal wave, which is a configuration that can be understood as a combination of the conventional technologies, the function of the modulation can be represented as the following expression.

f(α_{mod},ω_{mod},φ_{mod},t)=α_{mod} sin(ω_{mod}t+φ_{mod})

The output V(t) is represented by (Expression 4) below by using the nₜₕ-order Bessel function Jₙ.

$$V ( t ) = {V}_{0} \text{?} \text{?} ( 2 {α}_{mod} ) \text{?} ( 2 β ) cos ( n ( ( {ω}_{mod} t + {φ}_{mod} ) + m ( ( \text{?} t \text{?} ) + 2 {θ}_{0} ) \\ \text{?} \text{indicates text missing or illegible when filed}$$

In (Expression 4), when the initial polarization angle is θ₀=45° or θ₀=−45°, considering the measurement of a fine magnetic field with β<<1, the higher-order terms of the Bessel function regarding β are ignored.

When the magnetic field is zero and the amplitude of the modulation is α_{mod}=0, it indicates arrangement with which the outputs of the differential circuit 108 are canceled out to be zero. In this case, the output V(t) is represented by (Expression 5) below.

$$V ( t ) \approx - 2 {V}_{0} \text{?} {J}_{2 k - 1} ( 2 {α}_{mod} ) {J}_{0} ( 2 β ) sin ( ( 2 k - 1 ) {ω}_{mod} t + ( 2 k - 1 ) {φ}_{mod} ) - 2 {V}_{0} \text{?} {J}_{2 k} ( 2 {α}_{mod} ) {J}_{1} ( 2 β ) sin ( ( 2 k {ω}_{mod} + {ω}_{s} ) t + 2 k {φ}_{mod} + {φ}_{s} ) + 2 {V}_{0} \text{?} {J}_{2 k} ( 2 {α}_{mod} ) {J}_{1} ( 2 β ) sin ( ( 2 k {ω}_{mod} - {ω}_{s} ) t + 2 k {φ}_{mod} + {φ}_{s} ) \\ \text{?} \text{indicates text missing or illegible when filed}$$

At this time, a response to the measured magnetic field, which is represented by the second term and the third term, is maximized.

At this time, the first term represents an oscillation of the polarization plane caused by the sinusoidal wave modulation. When the polarization plane of the light is shifted from the balanced position by the modulation, the light intensity noise is not differentiated but remains as a noise.

Therefore, even if the balanced detection by the polarization splitter and the sinusoidal wave modulation are simply combined, it is not possible to achieve both the reduction of the light intensity noise and the reduction of the 1/f noise in a simultaneous manner. As a result, it is found that βₘᵢₙ as the lower limit of β in this case is represented by the following expression.

$${β}_{min} \approx \frac{\sqrt{\begin{matrix}{\vert \text{?} {J}_{2 k - 1} ( 2 {α}_{mod} ) ( {\tilde{V}}_{0} ( ( 2 k - 1 ) {ω}_{mod} - {ω}_{s} ) - {\tilde{V}}_{0} ( ( 2 k - 1 ) {ω}_{mod} {ω}_{s} ) ) \vert}^{2} + \\ {\vert {V}_{sys} ( {ω}_{mod} + \text{?} ) \vert}^{2}\end{matrix}}}{{J}_{2} ( 2 {α}_{mod} ) {\tilde{V}}_{0} ( 0 )}$$

$$\text{?} \text{indicates text missing or illegible when filed}$$

A qualitative description on the configuration of this embodiment is described below with reference to the drawings.

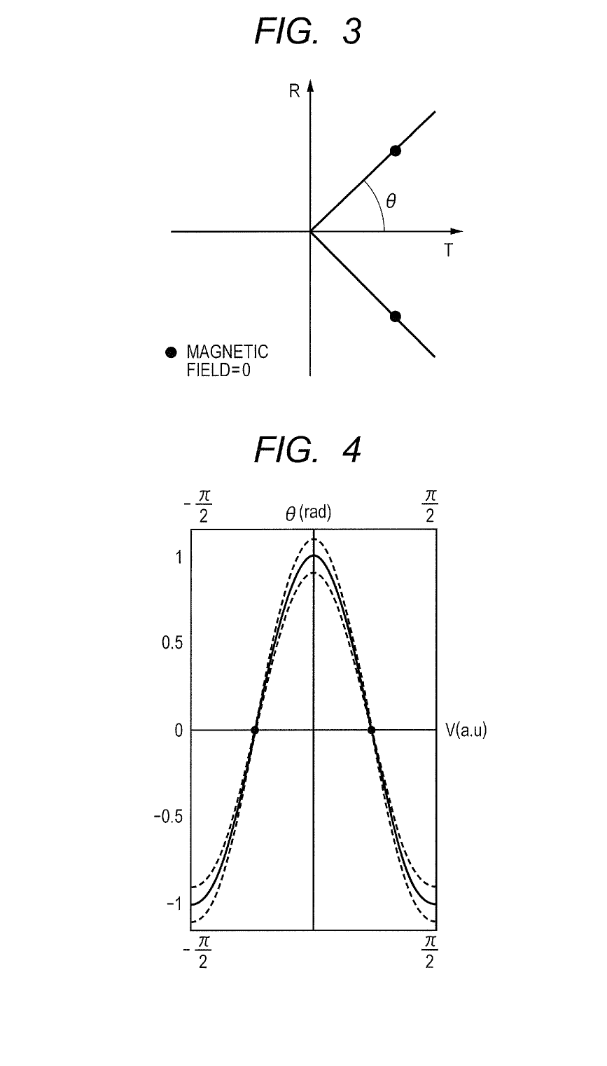

FIG. 3 is a schematic diagram illustrating a polarization state of the linearly polarized probe light.

The horizontal axis and the vertical axis represent the amplitude in a transmission direction and the amplitude in a reflection direction of the polarization splitter 105 among electric field vectors.

A symbol “” represents two polarization states that are periodically switched when the modulation of the polarization angle of the rectangular wave is applied between θ=π/4 and θ=−π/4 in the case where the measured magnetic field is zero.

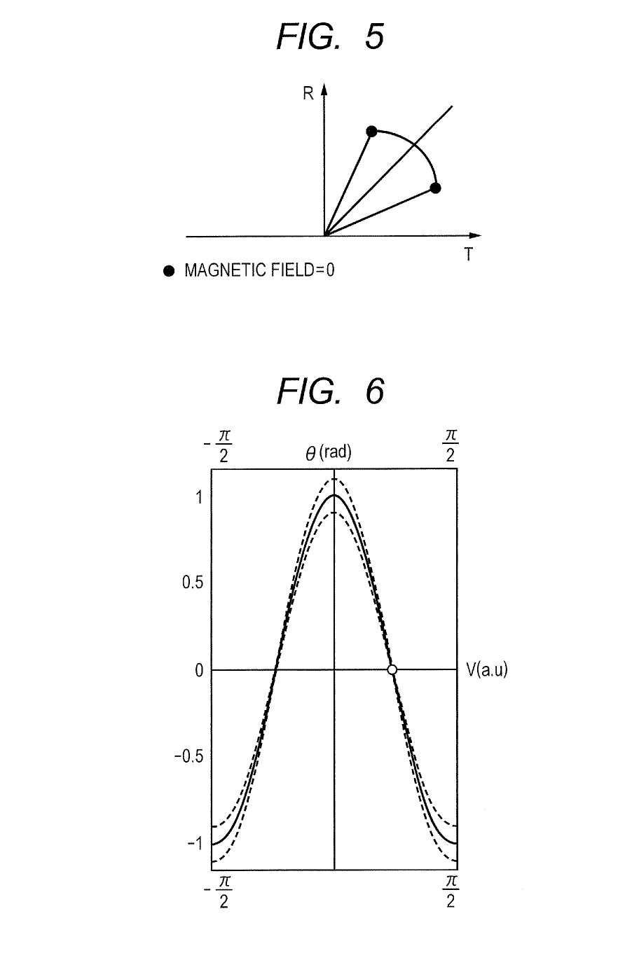

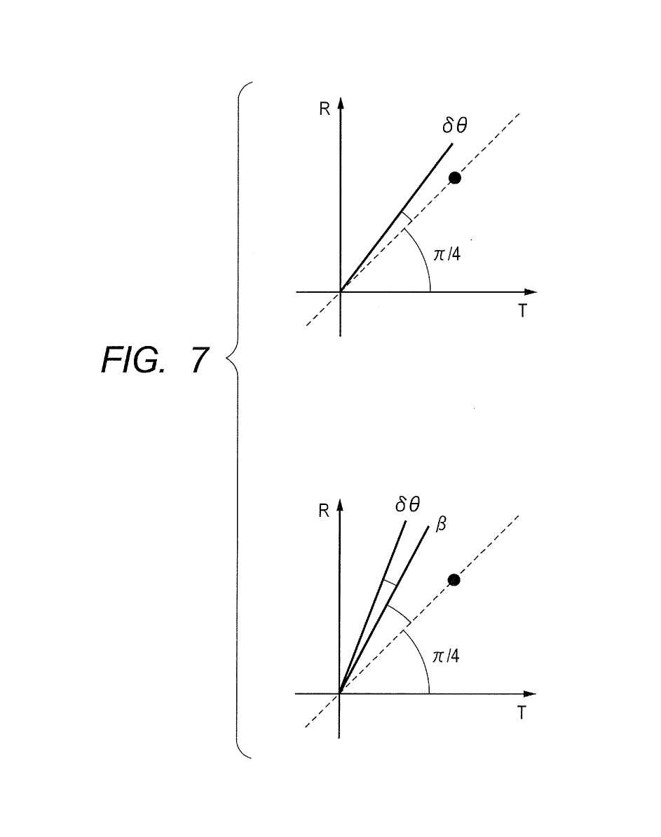

The output from the photodetector 106 that is arranged at a transmission port of the polarization splitter 105 becomes V₀ cos²θ with respect to the polarization angle θ, and the output from the photodetector 107 that is arranged at a reflection port becomes V₀ sin²θ with respect to the polarization angle θ. A solid line in FIG. 4 represents a difference between these two outputs.

On the other hand, a dotted line in FIG. 4 represents a variation of the difference between the outputs from the photodetectors 106 and 107 with a change of the light intensity.

The dotted line in FIG. 4 represents a condition in which the output with respect to the polarization angle θ is (V₀+δV)cos 2θ and (V₀−δV)cos 2θ.

Two points indicated by “” are constant regardless of the variation of the light intensity noise. When measuring a fine magnetic field by using the rectangular wave modulation, the measurement is performed while switching these points in an alternate manner. Therefore, the influence of the light intensity noise is reduced.

Referring to FIGS. 5 and 6, a case is considered where a modulation is applied with an amplitude α, and θ₀=π/4. This is a case of Comparative Example 1 as opposed to the embodiment of the present invention.

The results of FIGS. 5 and 6 respectively correspond to those of FIGS. 3 and 4. Two points indicated by “” shown in FIG. 5 are switched by the modulation.

An amplitude required for this modulation is much larger than the rotation angle of the polarization plane by the fine magnetic field.

Therefore, even when differential measurement is performed, the measurement is performed in an area other than a point indicated by “o”, where the influence of the light intensity noise is received, for most measurement time. For this reason, the influence of the light intensity noise cannot be avoided.

Further, because the light intensity noise is reduced by the difference detection in the modulation using the rectangular wave, a modulation frequency can be selected regardless of the spectrum of the light intensity noise. Therefore, by selecting a frequency area where a system noise is small, it is possible to achieve a further reduction of a sensor noise.

Next, a case where the amplitude of the rectangular wave modulation is slightly deviated from 45° is considered. In this case, when the amplitude is deviated by a small amount δα, (Expression 2) becomes (Expression 6) below.

$$V ( t ) = {V}_{0} cos ( 2 β sin ( \text{?} t + {φ}_{s} ) + 2 {θ}_{0} + 2 \cdot ( \frac{π}{4} + δ α ) sgn ( sin ( {ω}_{mod} t + {φ}_{mod} ) ) ) \approx - sin ( 2 δ α ) V \text{?} + ( 2 δ α ) ( {V}_{sin , 0} + \text{?} )$$

$$\text{?} \text{indicates text missing or illegible when filed}$$

In (Expression 6), V_{nomod} is represented by (Expression 7) below.

V_{nomod}=V₀ cos(2β sin(ωₛt+φₛ)+2θ₀))sin(2δα)

V_{sin,0} and V_{cos,1} are represented by the above-mentioned (Expression 3). The response to the measured magnetic field is represented by V_{cos,1}. (Expression 6) indicates that the response to the measured magnetic field is reduced by cos(2δα) when the amplitude is deviated from 90° by δα. This is because a part of the response to the magnetic field remains in the original band without being modulated. This is represented by V_{nomod}.

It is preferred that the magnitude of the deviation δα of the amplitude from 45° be equal to or smaller than 13 degrees with which cos 2δα=0.9, because a degradation of the response to the measured magnetic field is suppressed up to 10%.

If the amplitude is deviated by 13 degrees on one side, the angle of the modulation is preferred to be within 64° to 116° with respect to each other.

In addition, in this embodiment, it is possible to realize a magnetic force measurement method in which a magnetic field intensity is measured by the following method.

That is, a cell containing a group of alkali metal atoms is prepared, and probe light having a linearly polarized light component enters the cell.

The angle of the polarization plane of the probe light is modulated to detect a change of the angle of the polarization plane of the probe light transmitted through the cell.

At this time, a magnetic force measurement method can be realized in which rectangular wave modulation is applied with respect to the angle of the polarization plane of the probe light and a difference of the light intensity between components separated by using a polarization splitter is measured.

### Example

An example to which the present invention is applied is described below.

As the example, a configuration example of an optically pumped magnetometer to which the present invention is applied is described with reference to FIG. 2.

The optically pumped magnetometer according to this example includes a cell 201 containing potassium (K), a pump light source 202, a probe light source 203, linear polarizers 204 and 205, and an electro-optical phase modulation element 206.

The optically pumped magnetometer further includes quarter wavelength plates 207 and 208, a half wavelength plate 209, a polarization splitter 210, photodetectors 211 and 212, a differential circuit 213, a lock-in amplifier 214, and a random wave generator 215.

In addition, the optically pumped magnetometer further includes an isothermal insulating oven 221, a three-axis Helmholtz coil 222, optical windows 223, 224, and 225, and an optical terminator 226.

A specific configuration of the cell according to this example is described. The cell 201 in this example includes a material transparent to probe light and pump light, such as glass.

The cell 201 holds potassium (K) as an alkali metal atom in its inside, and is gas tight.

In addition, helium (He) and nitrogen (N₂) are also held as a buffer gas and a quencher gas.

Because the buffer gas suppresses a diffusion of the polarized alkali metal atom, it is effective to suppress a spin relaxation due to a collision with a cell wall to enhance the polarization rate.

Further, N₂ gas is a quencher gas that derives energy of K in an excited state and suppresses fluorescence, which is effective to increase the efficiency of the optical pumping.

The K atom has the smallest scattering cross-section in a spin polarization disruption due to a collision between the K atoms and between a K atom and a He atom among the alkali metal atoms.

Therefore, the potassium is preferred as an alkali metal to fabricate a magnetic sensor having a long relaxation time and a strong signal intensity.

A specific configuration of the isothermal insulating oven according to this example is described.

The isothermal insulating oven 221 is installed around the cell 201.

At the time of measurement, the cell 201 is heated to the maximum temperature of about 200 degrees Celsius in order to increase a density of the alkali metal gas in the cell 201.

A heating method involves heating the cell 201 by flowing a heated inert gas into the isothermal insulating oven 221 from outside. The isothermal insulating oven 221 takes a role of preventing this heat from escaping to the outside.

In the isothermal insulating oven 221, the optical windows 223 and 224 are installed on an optical path of probe light 216, and the optical window 225 is installed on an optical path of pump light 217, thus securing the optical paths of the pump light 217 and the probe light 216.

Further, the optical terminator 226 is installed on the optical path of the pump light 217 which has transmitted through the cell 201, to perform a termination process.

A specific configuration of the three-axis Helmholtz coil according to this example is described.

Around the isothermal insulating oven 221, the three-axis Helmholtz coil 222 is installed in a magnetic shield (not shown).

This magnetic shield reduces a magnetic field penetrating from an external environment. The three-axis Helmholtz coil 222 is used to control a magnetic field environment around the cell 201.

A bias magnetic field of the same direction as a direction of the pump light (z direction in FIG. 2) is applied to the magnetic field environment of around the cell 201 such that a measurement frequency and a Larmor frequency match each other to resonate.

Further, this magnetic shield is used to make an environment in which residual magnetic fields in the other directions (x and y directions in FIG. 2) are canceled out so that no magnetic field is applied.

In addition, a seam coil may be further installed to compensate an uneven magnetic field.

A specific configuration of the pump light source according to this example is described.

A wavelength of the pump light 217 emitted from the pump light source 202 is set to the D1 transition wavelength of the K atom.

The polarization of the pump light 217 is shaped to a linear polarization by the linear polarizer 204, and then converted into a circular polarization by the quarter wavelength plate 207. At this time, the polarization may be converted in either a right circular polarization or a left circular polarization.

A specific configuration of the probe light source according to this example is described.

A wavelength of the probe light 216 emitted from the probe light source 203 is detuned from the D1 transition wavelength of the potassium atom by a few GHz such that a signal response is maximized.

A value of the detuning to maximize the signal response depends on pressure and temperature of the buffer gas of the cell 201.

The probe light 216 is linearly polarized by the linear polarizer 205.

A specific configuration of the polarization modulation system according to this example is described.

When a voltage is applied to the electro-optical phase modulation element 206 by the random wave generator 215, a birefringence of the crystal is changed in proportion to the voltage.

The change of the birefringence causes a change of a phase difference with respect to the light transmitting through the crystal, to thereby change the polarization state of the light.

The phase difference of the probe light 216 that entered in a linearly polarized state is changed in response to the voltage applied to the electro-optical phase modulation element 206, and thus the polarization state becomes an elliptically polarized state.

The change of the phase difference is converted into a rotation of a linear polarization plane by rotating the angles of the electro-optical phase modulation element 206 and the subsequent quarter wavelength plate 208 around their crystal axis direction in an appropriate manner, respectively.

As a result, when a rectangular wave voltage is applied to the electro-optical phase modulation element 206, the polarization plane of the probe light 216 is oscillated in a rectangular wave shape.

Because the amplitude of the oscillation is proportional to the voltage applied to the electro-optical phase modulation element 206, an appropriate voltage is applied to the electro-optical phase modulation element 206 such that a total amplitude becomes 90°.

It is preferred that a repetition frequency of the rectangular wave be 1 kHz or higher. In addition to this, a method of modulating the polarization plane by a magnetic field using a Faraday effect can be considered. In this case, in order to reduce an influence on the magnetometer side due to a varying magnetic field used for the modulation of the polarization plane, it is preferred that measures be taken to place away or shield a modulator.

A specific configuration of the polarization measurement system according to this example is described.

The polarization measurement system includes the half wavelength plate 209, the polarization splitter 210, the photodetectors 211 and 212, the differential circuit 213, and the lock-in amplifier 214.

The polarization splitter 210 divides the light into two light beams having an intensity ratio of cos²θ:sin²θ in accordance with the polarization angle θ of the incident light.

In this case, the polarization state with which the incident light is all transmitted is taken as a reference of θ=0°.

The optical intensities of the two divided light beams are measured by the photodetectors 211 and 212, respectively, and a difference between outputs of the photodetectors 211 and 212 is read by the differential circuit 213.

When the light enters the polarization splitter 210 at the polarization angle of θ=45° or θ=−45°, the light is divided with the same intensity, and an output of the differential circuit 213 becomes zero.

When there is no measured magnetic field, the polarization plane of the probe light 216 is oscillated in a rectangular wave shape with a total amplitude of 90°.

The half wavelength plate 209 is rotated around its crystal axis direction as a rotation axis, and the polarization plane of the probe light 216 is rotated to take θ=45° or θ=−45° in an alternate manner. Accordingly, the probe light 216 is constantly divided with the equal light intensity by the polarization splitter 210, and hence the output of the differential circuit 213 becomes zero.

Next, a case where there is a measured magnetic field is considered.

The probe light 216 which has transmitted through the cell 201 and read the measured magnetic field as the rotation of the polarization plane is divided by the polarization splitter 210, and the optical intensities of the divided light beams are measured by the photodetectors 211 and 212, respectively.

A difference between the outputs of the photodetectors 211 and 212 is read by the differential circuit 213, and lock-in detection is performed by the lock-in amplifier 214. The modulation signal applied to the electro-optical phase modulation element 206 by the random wave generator 215 is used for demodulation.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-075619, filed Mar. 29, 2012, which is hereby incorporated by reference herein in its entirety.

1. An optically pumped magnetometer using one of an electron spin and a nuclear spin of an atom, the optically pumped magnetometer comprising:
a cell containing a group of alkali metal atoms therein;
a probe light optical system for making probe light having a linearly polarized light component enter the cell;
a modulation unit for applying modulation to an angle of a polarization plane of the probe light; and
a detector for detecting a change of the angle of the polarization plane of the probe light transmitted through the cell,
wherein the modulation unit allows rectangular wave modulation to the angle of the polarization plane of the probe light, and
wherein the detector includes:
a polarization splitter; and
a differential circuit for obtaining a difference in light intensity between components separated by the polarization splitter.

2. The optically pumped magnetometer according to claim 1, wherein the rectangular wave modulation includes a modulation which is alternately switched to angles of two polarization planes having angles of 64° to 116° with respect to each other.

3. The optically pumped magnetometer according to claim 1, wherein the rectangular wave modulation includes a modulation which is alternately switched to angles of two polarization planes having an angle of 90° with respect to each other.

4. A magnetic force measurement method of measuring a magnetic field intensity, comprising the steps of:
preparing a cell containing a group of alkali metal atoms therein;
making probe light having a linearly polarized light component enter the cell;
applying modulation to an angle of a polarization plane of the probe light; and
detecting a change in the angle of the polarization plane of the probe light transmitted through the cell,
wherein the modulation applying step comprises applying rectangular wave modulation to the angle of the polarization plane of the probe light, and
wherein the detecting step comprises measuring a difference in light intensity between components separated by use of a polarization splitter.

5. The magnetic force measurement method according to claim 4, wherein the rectangular wave modulation comprises a modulation which is alternately switched to angles of two polarization planes having angles of 64° to 116° with respect to each other.

6. The magnetic force measurement method according to claim 4, wherein the rectangular wave modulation comprises a modulation which is alternately switched to angles of two polarization planes having an angle of 90° with respect to each other.
